(19) United States
(12) Patent Application Publication
(10) Pub. No.: US 2001/0023992 A1
(43) Pub. Date: Sep. 27, 2001

(54) Highly integrated system-on-chip system with non-volatile memory unit

(76) Inventor: Andreas Doll, Neubiberg (DE)

Correspondence Address: LERNER AND GREENBERG, P.A., Post Office Box 2480, Hollywood, FL, 33022-2480, US

(21) Appl. No.: 09/817,964

(22) Filed: Mar. 27, 2001

(30) Foreign Application Priority Data
Mar. 27, 2000 (DE) 100 15 193.0

(51) Int. Cl. H01L 23/48; H01L 23/52; H01L 29/40

(52) U.S. Cl. 257/777

(57) ABSTRACT

A highly integrated system-on-chip system with a non-volatile memory unit, includes a chip having an integrated MRAM memory unit, and semiconductor layers disposed underneath the MRAM memory unit and functioning merely as carriers for the MRAM memory unit. An integration density of the chip may be increased by using the semiconductor layers for additional integrated circuits.

### BACKGROUND OF THE INVENTION

1. Field of the Invention

The invention relates to a chip having a semiconductor substrate and an integrated circuit which contains a memory unit above the semiconductor substrate.

In order to be able to construct hardware applications effectively in the embedded sector, such as mobile telephones or cordless telephones, use is often made of microelectronic chips which combine both logic units and memory units on their chip area to form a single integrated circuit. Such microelectronic chips are referred to as “System-on-Chip” (SoC) systems.

It is advantageous for many SoC systems to use MRAM (Magnetoresistive Random Access Memory) memory units as the memory units, since they maintain all of the stored data when the supply voltage is interrupted. That effect is useful, for example, in mobile telephones in order not to lose stored telephone numbers when the mobile telephone is switched off.

The architecture of an MRAM cell field, which is known per se and is the main constituent part of an MRAM memory unit, is described in detail below with regard to FIG. 2.

In known SoC systems, the memory units and the logic units are integrated laterally on a chip, that is to say they are disposed beside one another on the chip area. The resulting long wiring paths between the logic units and the memory units may limit the maximum clock rate and therefore the operating speed of the chip. In order to counteract that effect, attempts are made to increase the lateral integration density as far as possible and therefore to shorten the wiring paths.

### SUMMARY OF THE INVENTION

It is accordingly an object of the invention to provide a highly integrated system-on-chip system with a non-volatile memory unit, which overcomes the hereinafore-mentioned disadvantages of the heretofore-known devices of this general type and which further increases an integration density of SoC systems, in particular those with MRAM memory components.

With the foregoing and other objects in view there is provided, in accordance with the invention, a chip, comprising a semiconductor substrate and an integrated circuit disposed above the semiconductor substrate. The integrated circuit contains an MRAM (Magnetoresistive Random Access Memory) memory unit having a memory cell field. The integrated circuit also contains parts implemented in the semiconductor substrate underneath the memory unit. The parts contain additional memory units.

Integrated circuits can be implemented substantially in two ways: the first possibility is to integrate the integrated circuit directly into a substrate. To that end, the substrate is subjected, for example, to mutually alternating evaporating processes of semiconductor layers and etching processes of the same.

The second possibility is to use the substrate merely as a carrier. In that case, the integrated circuit is therefore not etched into the substrate but is additionally place onto the substrate at the top.

One example of the second possibility is a SoC system which has MRAM memory units. In that case, a drive logic for the MRAM memory units, as part of the integrated circuit, is generally incorporated into that part of the substrate which is located beside the MRAM memory unit. The MRAM memory units themselves are disposed above another part of the substrate, that is to say they merely use the substrate as a carrier.

The substrate generally includes a carrier substrate and a number of semiconductor layers applied thereto. The semiconductor layers form a base layer of the integrated circuit and are applied initially, uniformly over the entire chip area, by evaporation processes. Subsequent etching processes are absent under the MRAM memory units, and the semiconductor layers function only as carriers therein and are not used for integrated circuits.

The core concept of the invention is to use the previously unused parts of the semiconductor layers, placed underneath the MRAM memory units, for additional integrated circuits such as logic units and/or memory units.

This has the advantage of permitting a substantially higher integration density of the integrated circuit on the chip to be implemented with only an insignificantly higher outlay in the fabrication process.

In accordance with another feature of the invention, the drive logic is no longer disposed in the parts of the semiconductor layers of the substrate beside the MRAM memory units, but is located in the parts of the semiconductor layers underneath the MRAM memory units. This permits the area required by the chip to be reduced considerably. One advantage of this embodiment is that wiring paths between the parts of the integrated circuit underneath the MRAM memory units and the MRAM memory units themselves are very short, which results in an increased operating speed of the chip.

In accordance with a further feature of the invention, the semiconductor layers underneath the MRAM memory units are used for additional logic units. It is therefore possible, for example, to process the data read from the MRAM memory units “on site”, which results in a savings in time during the second reading of data from the MRAM memory units, which is needed during this process, because of the short wiring paths. One example of this is a hard disc controller.

In accordance with a concomitant feature of the invention, the parts of the semiconductor layers of the substrate underneath the MRAM memory units are used for the integration of additional memory units. These memory units are preferably DRAM or SRAM based memories, which are distinguished by very short access times. This combination permits the slow access times to the MRAM memory units to be compensated for, since all of the data which is repeatedly read or written is kept for as long as possible in the additional, fast DRAM or SRAM memory units. It is only during the permanent saving of data, for example, that the data is then transferred into the MRAM memory cell field. This provides high integration of dynamic, volatile memories (for example working memories) and non-volatile memories (for example Boot MRAM, telephone number memory in mobile telephones), which permits great flexibility in the range of application.

Other features which are considered as characteristic for the invention are set forth in the appended claims.

Although the invention is illustrated and described herein as embodied in a highly integrated system-on-chip system with a non-volatile memory unit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view of an embodiment of a chip according to the invention; and

FIG. 2 is a fragmentary, perspective view showing a structure of an architecture of an MRAM memory cell field according to the prior art.

### DESCRIPTION OF THE PREFERRED EMBODIMENTS

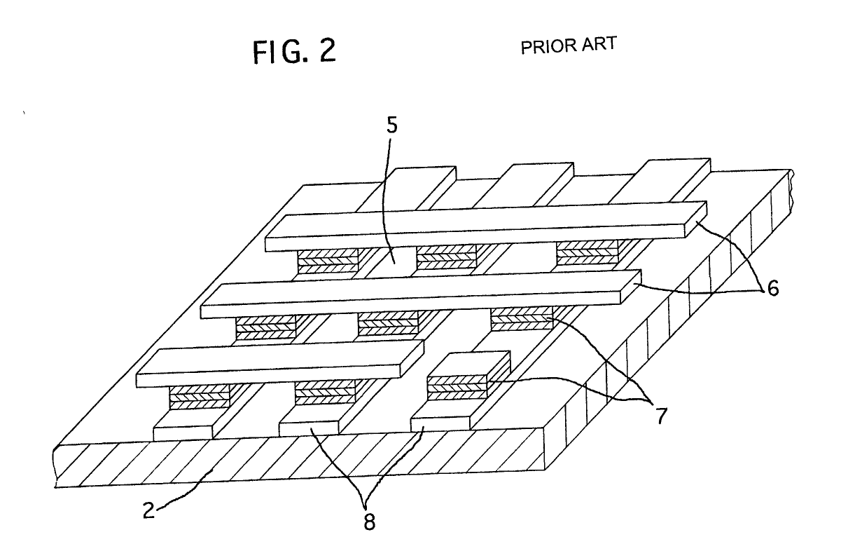

Referring now in detail to the figures of the drawings, in which mutually corresponding components are provided with the same reference symbols, and first, particularly, to FIG. 2 thereof, there is seen a diagrammatic illustration of the architecture of an MRAM cell field 5, which is known per se and is the main constituent part of an MRAM memory unit. The MRAM memory cell field 5 includes a large number of memory cells 7 which, at their upper and lower sides, are respectively framed by a metal strip 6, 8. These metal strips 6, 8 function as a word line 6 and as a column line 8. If a bit is to be written into a specific memory cell 7 or a bit is read from a specific memory cell 7, then the associated word line 6 and the associated column line 8 are activated. As a rule, the entire MRAM memory cell field 5 is located on a substrate 2 functioning as a carrier.

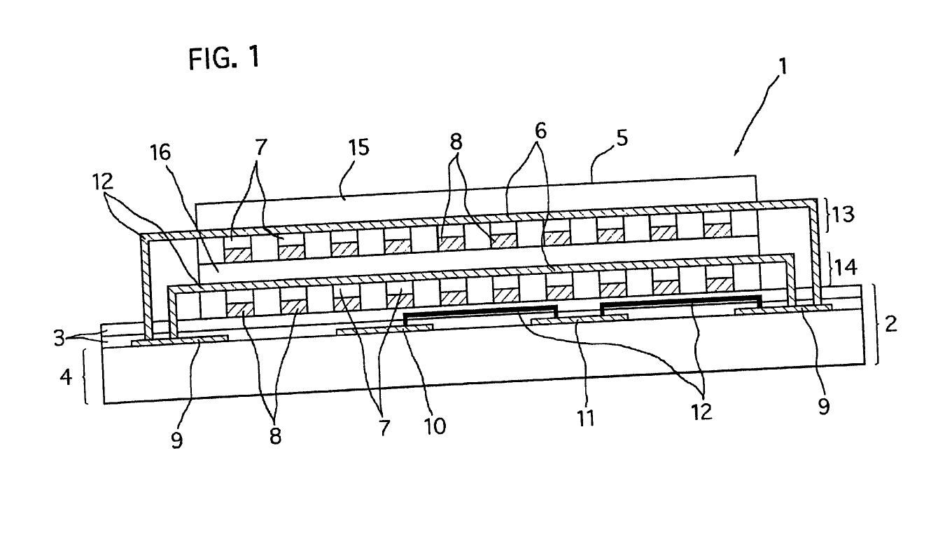

FIG. 1 shows a particularly preferred embodiment of a chip 1 according to the invention. A substrate 2 includes a carrier substrate 4 and a number of semiconductor layers 3 applied thereto. An MRAM memory unit, including a memory cell field 5, is disposed on the semiconductor substrate 2. This MRAM memory cell field 5 includes two memory cell field layers 13, 14 separated by an insulating interlayer 16, as well as an oxide protective layer 15 disposed above.

The carrier substrate 4 is preferably formed of a semiconductor material, such as silicon, but any other material suitable for this purpose can also be used.

Each of the two memory cell field layers 13, 14 preferably has the architecture described with regard to FIG. 2.

The word lines 6 are connected to a drive logic 9 underneath the MRAM memory cell field 5 through indicated wiring paths 12. Other wiring paths 12 connecting the column lines 8 with the drive logic 9 are not shown in FIG. 2.

The drive logic 9 and an additional integrated circuit, including an additional logic unit 10 and an additional DRAM memory unit 11, are integrated into the semiconductor layers 3. Therefore, the integrated circuit 9, 10, 11, 5 contains the memory cell field 5 and parts 9, 10, 11.

The illustrated wiring paths 12 between the additional integrated circuit 10, 11 and the MRAM memory cell field 5 are therefore very short.

Of course, the invention is not restricted to this specific embodiment, but can also be used on all chips which, at least to some extent, use a substrate merely as a carrier for memory cell fields respectively disposed above, or for parts of, an integrated circuit.

Likewise, the additional DRAM memory unit 11 is a specific exemplary embodiment. Any other type of memory which can be implemented at the semiconductor level (for example EEPROM, DDR-SDRAM (Double Data Rate Synchronous Dynamic RAM), . . . ) is possible.

I claim:

1. A chip, comprising:
a semiconductor substrate; and
an integrated circuit disposed above said semiconductor substrate;
said integrated circuit containing an MRAM (Magnetoresistive Random Access Memory) memory unit having a memory cell field; and
said integrated circuit containing parts implemented in said semiconductor substrate underneath said memory unit, and said parts containing additional memory units.

2. The chip according to claim 1, wherein said parts of said integrated circuit implemented underneath said memory unit also contain a drive logic for said MRAM memory cell field.

3. The chip according to claim 1, wherein said additional memory units are SRAM (Synchronous Random Access Memory) based memory cell fields.

4. The chip according to claim 1, wherein said additional memory units are DRAM (Dynamic Random Access Memory) based memory cell fields.

5. The chip according to claim 1, wherein said semiconductor substrate has an upper part with at least one semiconductor layer.

6. The chip according to claim 5, wherein said parts of said integrated circuit implemented underneath said memory unit are disposed in said at least one semiconductor layer.

7. The chip according to claim 1, wherein said semiconductor substrate has a lower part constructed of a material largely formed of silicon.
